(19) United States
(12) Patent Application Publication
(10) Pub. No.: US 2026/0081103 A1
(43) Pub. Date: Mar. 19, 2026

(54) NOTCH FILTER FOR HIGH THROUGHPUT X-RAY PHOTON SPECTROSCOPY

(71) Applicant: Applied Materials Israel Ltd., Rehovot (IL)

(72) Inventors: Martin Chauvin, Bures-sur-Yvette (FR); Alon Litman, Nes-Ziona (IL)

(73) Assignee: Applied Materials Israel Ltd., Rehovot (IL)

(21) Appl. No.: 18/888,033

(22) Filed: Sep. 17, 2024

(51) Int. Cl. H01J 37/244; H01J 37/147

(52) U.S. Cl. CPC H01J 37/244; H01J 37/147; H01J 2237/057; H01J 2237/2442; H01J 2237/2445

(57) ABSTRACT

Disclosed herein is a sample characterization system including a characterization tool configured to generate an electron beam directed toward a tested sample; an X-ray photon energy dispersive detector (EDX) configured to collect X-ray photons emitted from the tested sample; and a filter assembly positioned in the characterization tool between the tested sample and the EDX, the filter assembly including a band-stop filter configured to allow transmission therethrough of information-carrying X-ray photons having a predetermined energy range and preventing irrelevant photons having an energy range different from the predetermined energy range from reaching the EDX, whereby a ratio between a count of information-carrying X-ray photons reaching the EDX and an overall photon count reaching the EDX is increased as compared to a sample characterization system without the filter assembly.

### TECHNICAL FIELD

The present disclosure relates generally to manufacturing and metrology of specimens.

### BACKGROUND OF THE INVENTION

The ongoing trend of semiconductor device shrinking, combined with the integration of multiple elements therein, has generated a need for manufacturing and metrology techniques operating at the nanometric scale. This need becomes particularly pronounced in the field of mass production, as semiconductor devices continue to adopt complex geometries, such as 3D chips.

One of the main methods for determining sample composition during the manufacturing process includes the utilization of X-ray spectroscopy using energy dispersive detectors (EDX). This is often accomplished utilizing systems such as scanning electron microscopes equipped with EDX detectors. However, the efficacy of such measurements may be impeded by the count rate of the EDX detector.

Hence, there is a need in the art for systems and methods facilitating rapid and reliable composition analysis.

### BRIEF SUMMARY OF THE INVENTION

Aspects of the disclosure, according to some embodiments thereof, relate to manufacturing and metrology of specimens.

More specifically, but not exclusively, aspects of the disclosure, according to some embodiments thereof, relate to manufacturing and characterization of specimens, such as wafers, photoresists, semiconductor devices and/or components thereof.

Thus, according to an aspect of some embodiments, there is provided a sample characterization system including:
(a)a characterization tool configured to generate an electron beam directed toward a tested sample, such as but not limited to a wafer;
(b)an X-ray photon energy dispersive detector (EDX) configured to collect X-ray photons emitted from the tested sample; and
(c)a filter assembly positioned in the characterization tool, between the tested sample and the EDX. The filter assembly includes a band-stop filter configured to allow transmission therethrough of information-carrying X-ray photons having a predetermined energy range while preventing/attenuating irrelevant photons having an energy range different from the predetermined energy range from reaching the EDX. In this way, a ratio between the count of information-carrying X-ray photons reaching the EDX and an overall photon count reaching the EDX is increased, as compared to a sample characterization system without the filter assembly.

According to some embodiments, the filter assembly may further include an electron filter configured to attenuate back-scattered and/or secondary electrons emitted from the tested sample. According to some embodiments, the electron filter also absorbs/attenuates photons. According to some embodiments, the electron filter is configured to attenuate parasitic photons to a larger extend than the information carrying electrons. According to some embodiments, the filter assembly may, in addition to the electron filter or instead of the electron filter, include a deflector configured to deflect electrons away from the filter assembly.

According to some embodiments, the filter assembly may further include one or more additional band-stop filters. According to some embodiments, each of the one or more additional band-stop filters may be configured to filter out/absorb/attenuate X-ray photons having a different respective predetermined energy of X-ray photons.

According to some embodiments, at least a portion of the band-stop filter may be made of or include a plurality of thin films. According to some embodiments, the thickness of each of the plurality of thin films is in a range of 50 nm to 5 um, in a range of 500 nm to 5 um or in a range of 1000 nm to 5 um. Each possibility is a separate embodiment. According to some embodiments, at least a portion of the plurality of thin films include: Hf, Al, BN, TiN, Si₃N₄, V, Ti, Teflon, Mn, Cr, Fe, Al₂O₃ or any combination thereof. Each possibility is a separate embodiment.

According to some embodiments, at least a portion of the plurality of thin films include:
a. Mylar and Hf,
b. Mylar and Fe,
c. Mylar and Al₂O₃, or
d. Al and Mg.

According to some embodiments, the band-stop filter is a notch filter.

According to some embodiments, the filter assembly or parts thereof are replaceable in-situ. According to some embodiments, the predetermined energy range depends on the material from which the filter is made, thereby allowing tailoring a value thereof.

According to some embodiments, the ratio is increased by a factor of 8 or more.

According to some embodiments, the predetermined energy range is about 50 eV to 15 KeV. According to some embodiments, the predetermined energy range is about 50 eV to 30 KeV.

According to some embodiments, the characterization tool includes an electron microprobe, a scanning electron microscope (SEM), a transmission electron microscope (TEM), or a scanning TEM (STEM). Each possibility is a separate embodiment.

There is provided, according to some embodiments, a method for filtering photons by energy, including:
(a)directing a primary electron beam onto a tested sample, thereby initiating emission of X-ray photons and electrons from the tested sample;
(b)attenuating X-ray photons having an energy different than a predetermined energy range of information-carrying X-ray photons by using a band-stop filter, positioned between the tested sample and the EDX;
(c)detecting, by the EDX, the information-carrying X-ray photons, thereby a ratio between a count of information-carrying X-ray photons reaching the EDX and an overall photon count reaching the EDX is increased as compared to a sample characterization system without the filter assembly; and
(d)outputting signals indicative of the information-carrying X-ray photons detected by the EDX.

According to some embodiments, the method further includes attenuating back-scattered electrons and/or secondary electrons emitted from the tested sample using an electron filter. Additionally, or alternatively, the method may further include deflecting backscattered and/or secondary electrons away from the filter assembly. According to some embodiments, the electron filter may further attenuate a portion of the emitted photons. According to some embodiments, the electron filter may be configured to absorb/attenuate parasitic electron while allowing transmission therethrough of information carrying photons.

There is provided, according to some embodiments, a filter assembly for filtering photons by energy. According to some embodiments, the filter assembly includes a band-stop filter configured to allow transmission therethrough of information carrying X-ray photons having a predetermined energy range and preventing/inhibiting irrelevant photons from reaching an energy dispersive detector (EDX). In this way, a ratio between the count of information-carrying X-ray photons reaching the EDX and the overall photon count, reaching the EDX is increased, as compared to a sample characterization system without the filter assembly.

According to some embodiments, at least a portion of the band-stop filter is made of or includes a plurality of thin films having a thickness of about 50 nm to 5 um. According to some embodiments, at least a portion of the plurality of thin films includes a material selected from: Hf, Al, BN, TiN, Si₃N₄, V, Ti, Teflon, Mn, Cr, Fe or Al₂O₃. Each possibility is a separate embodiment.

According to some embodiments, the ratio of counts is increased by a factor of 8 or more.

According to some embodiments, the filter assembly further includes an electron filter configured to attenuate back-scattered electrons and/or secondary electrons, emitted from the tested sample. Additionally, or alternatively, the filter assembly includes a deflector configured to deflect electrons away from the filter assembly.

According to some embodiments, at least a portion of the plurality of thin films include:
a. Mylar and Hf,
b. Mylar and Fe,
c. Mylar and Al₂O₃, or
d. Al and Mg.

According to some embodiments, the predetermined energy is in a range of 50 eV to 15 KeV. According to some embodiments, the predetermined energy is in a range of 50 eV to 30 KeV.

Certain embodiments of the present disclosure may include some, all, or none of the above advantages. One or more other technical advantages may be readily apparent to those skilled in the art from the figures, descriptions, and claims included herein. Moreover, while specific advantages have been enumerated above, various embodiments may include all, some, or none of the enumerated advantages.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

### BRIEF DESCRIPTION OF THE DRAWINGS

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

In the figures:

FIG. 1 presents a block diagram of a system for characterizing samples, according to some embodiments;

FIGS. 2A-2C present a schematic illustration of a cross-sectional side view of a filter system for filtering photons by energy, according to some embodiments;

FIG. 3A presents a flowchart of a method for filtering photons by energy, according to some embodiments;

FIG. 3B presents a schematic illustration of a working principle of the method and the system for filtering photons by energy, according to some embodiments; and

FIG. 3C presents a schematic illustration of a plot of the transmission as a function of the photon energy, according to some embodiments.

### DETAILED DESCRIPTION OF THE INVENTION

The principles, uses, and implementations of the teachings herein may be better understood with reference to the accompanying description and figures. Upon perusal of the description and figures present herein, one skilled in the art will be able to implement the teachings herein without undue effort or experimentation.

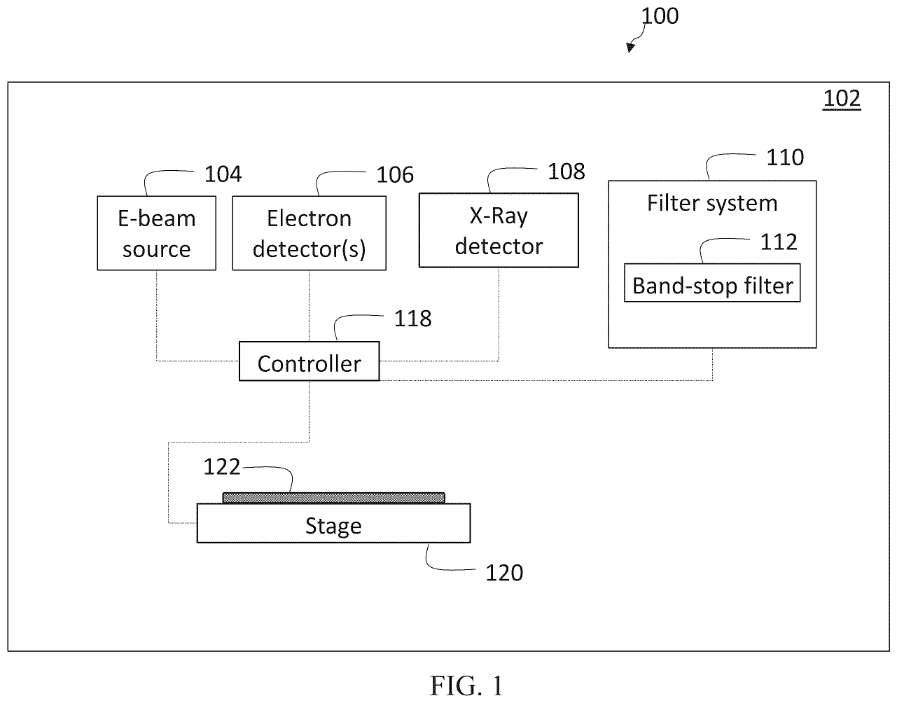

According to an aspect of some embodiments, there is provided a system for characterizing specimens. FIG. 1 presents a block diagram of an example of such a system, a system 100, according to some embodiments. System 100 includes a characterization tool 102.

According to some embodiments, characterization tool 102 may include an electron microprobe, a scanning electron microscope (SEM), a transmission electron microscope (TEM), a scanning TEM (STEM), and the like. Each possibility is a separate embodiment.

According to some embodiments, characterization tool 102 includes a stage 120 configured to accommodate a sample 122. As a non-limiting example, sample 122 may include an inspected specimen in the form of a patterned wafer, a non-patterned wafer, a semiconductor device or a component thereof, and the like.

According to some embodiments, stage 120 may be movable. According to some embodiments, stage 120 may be detachable.

According to some embodiments, characterization tool 102 is configured to generate an electron beam directed toward sample 122 and to collect data therefrom. More specifically, in some embodiments, characterization tool 102 includes an electron beam (e-beam) source 104 configured to generate an e-beam (i.e., a primary e-beam) directed towards sample 122.

According to some embodiments, e-beam source 104 may include an electron gun. As a non-limiting example, wherein characterization tool 102 includes a SEM, the e-beam generated by e-beam source 104 may have an acceleration voltage in a range of about 1KV to about 30 KV.

According to some embodiments, characterization tool 102 includes electron detector(s) 106 configured to detect electrons emitted from sample 122 as a result of the striking of the e-beam into sample 122. In some embodiments, the electrons emitted from sample 122 may include secondary electrons and/or backscattered electrons emitted therefrom.

According to some embodiments, characterization tool 102 includes an X-ray detector 108. In some embodiments, X-ray detector 108 includes an energy dispersive detector (i.e., an EDX detector). In some embodiments, X-ray detector 108 is configured to detect X-ray photons emitted from sample 122 as a result of the striking of the e-beam into sample 122.

In some embodiments, characterization tool 102 may optionally include one or more additional detectors, such as but not limited to, optical detectors, electrostatic lenses and/or deflectors, magnetic lenses and/or deflectors, and the like, or any combination thereof (not shown).

In some embodiments, characterization tool 102 may optionally include one or more vacuum pumps (not depicted). In some embodiments, the one or more vacuum pumps may be configured to maintain a vacuum environment within characterization tool 102. As a non-limiting example, characterization tool 102 may be operable under an ultra-high vacuum regime.

According to some embodiments, and as depicted in FIG. 1, characterization tool 102 includes a filter system 110. According to some embodiments, filter system 110 is configured to be positioned between sample 122 in characterization tool 102 and X-ray detector 108, such that a ratio of counts of X-ray photons of interest (also referred to herein as “information-carrying photons”) reaching detector 108 over overall photon counts reaching detector 108 is increased. According to some embodiments, the ratio of counts of X-ray photons of interest may be increased by a factor of at least about 6, by the factor of at least about 7, by the factor of at least about 8, by the factor of at least about 9, and by the factor of at least about 10. Each possibility is a separate embodiment.

In some embodiments, the ratio of counts of X-ray photons of interest may be increased by a factor in a range of about 6 to about 10, by the factor in the range of about 8 to about 10, by the factor in the range of about 9 to about 10. Each possibility is a separate embodiment.

Advantageously, in some embodiments, increasing the ratio of counts of X-ray photons of interest may be achieved by filtering system 110 without changing X-ray detector hardware of characterization tool 102.

According to some embodiments, filter system 110 may be replaceable in-situ.

According to some embodiments, filter system 110 includes a band-stop filter 112. According to some embodiments, filter system 110 is a notch filter. Each possibility is a separate embodiment.

According to some embodiments, band-stop filter 112 is configured to attenuate/filter out X-ray photons having a pre-determined energy prior to reaching an X-ray photon energy dispersive detector. Thereby, in some embodiments, increasing/maximizing the output count rate of photons of interest reaching the X-ray photon energy dispersive detector. Put differently, in some embodiments, filtering system 110 may be configured to (i) increase the relative fraction of photons of interest reaching the detector, and to (ii) reduce the photon input count rate by filtering out/removing irrelevant photons from reaching the detector. In some embodiments, the irrelevant photons may include a majority of photons reaching the detector. As a non-limiting example, wherein sample 122 includes a Si wafer, the irrelevant photons reaching an EDX detector may include Si photons.

According to some embodiments, band-stop filter 112 may optionally include electron filter for attenuating backscattered electrons and/or secondary electrons, as elaborated in greater detail elsewhere herein. In some embodiments, the electron filter is configured to attenuate back-scattered electrons and/or secondary electrons emitted from sample 122. According to some embodiments, the electron filter is positioned such that the electrons are attenuated prior to reaching band-stop filter 112, thereby preventing the electron to cause excitation of photons as a result of encountering band-stop filter 112.

According to some embodiments, band-stop filter 112 may optionally include one or more additional band-stop filters. In some embodiments, each of the one or more additional band-stop filters is configured to attenuate/filter out X-ray photons having a different respective predetermined energy of X-ray photons.

According to some embodiments, band-stop filter 112 may be made of or include a plurality of thin films, as elaborated in greater detail elsewhere herein.

According to some embodiments, and as depicted in FIG. 1, characterization tool 102 includes a controller 118. According to some embodiments, controller 118 may be functionally associated with any one or more components of characterization tool 102. According to some embodiments, controller 118 may be functionally associated with stage 120. According to some embodiments, controller 118 controller 118 may be configured to control and/or synchronize operation and functions of any one or more of components of characterization tool 102, such as but not limited to, stage 122, the one or more vacuum pumps, e-beam source 104, electron detector(s) 106, X-ray detector 108, and the like, or any combination thereof. Each possibility is a separate embodiment.

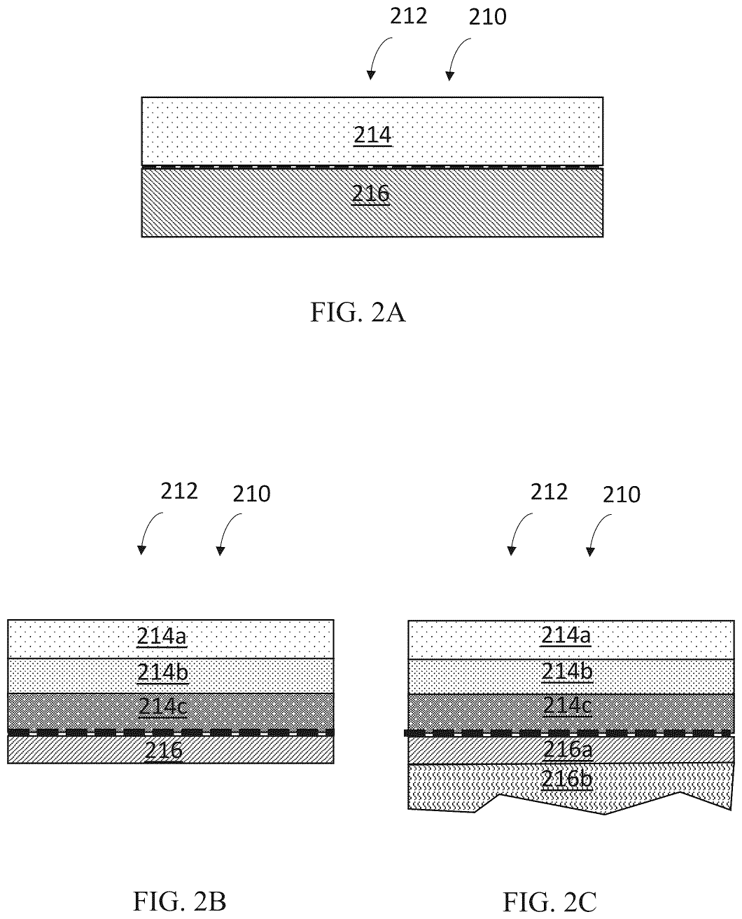

According to an aspect of some embodiments, there is provided a filter system for filtering photons by energy. FIG. 2A schematically illustrate a cross-sectional side view of an example of a filtering system 210, according to some embodiments. According to some embodiments, filtering system 210 may be identical, similar or different than filtering system 110 of FIG. 1.

According to some embodiments, filtering system 210 includes a band-stop filter 212. In some embodiments, band-stop filter 212 may be a notch filter.

According to some embodiments, at least a portion of band-stop filter 212 is made of or includes a plurality of thin films, as shown in FIG. 2B. In some embodiments, the plurality of thin films may be stacked one above the other.

In some embodiments, a thickness of each of the plurality of thin films may be substantially similar or identical. In some embodiments, the thickness of each of the plurality of thin films may be different. In some embodiments, a first portion of the plurality of thin films may have substantially the same thickness, and a second portion of the plurality of thin films may have different thicknesses. Each possibility is a separate embodiment.

n some embodiments, the thickness of each of the plurality of thin films may be in a range of about 50 nm to about 5 um, about 50 nm to about 10 nm, about 50 nm to about 20 nm, about 40 nm to about 20 nm, about 30 nm to about 5 nm, about 10 nm to about 5 nm, and the like. Each possibility is a separate embodiment.

According to some embodiments, at least a portion of the plurality of thin films may be selected from: Hf, Al, BN, TiN, Si₃N₄, V, Ti, Teflon, Mn, Cr, Fe or Al₂O₃, as elaborated in greater detail elsewhere herein.

In some embodiments, band-stop filter 212 may optionally include an electron filter 216 (FIG. 2A and FIG. 2B). According to some embodiments, electron filter 216 may include a back-scattered electrons filter configured to attenuate/filter-out back-scattered electrons emitted from a sample. According to some embodiments, electron filter 216 may be configured to attenuate/filter-out secondary electrons emitted from the sample. According to some embodiments, electron filter 216 may be configured to attenuate/filter-out back-scattered electrons and secondary electrons emitted from a sample. Each possibility is a separate embodiment.

In some embodiments, the back-scattered electrons and/or the secondary electrons may be emitted from the tested sample due to striking thereof with a primary e-beam. Put differently, in some embodiments, the emitted back-scatted electrons and/or secondary electrons may be referred to as parasitic/irrelevant signals emitted form tested sample. In some embodiments, the back-scatted electrons and/or secondary electrons may result in photons being emitted from band-stop filter 212, thus resulting in transmission of parasitic photons.

According to some embodiments, electron filter 216 may be made of or include a plurality of thin films. According to some embodiments, and as schematically depicted in FIG. 2C, electron filter 216 may include a first and a second thin film layers 216a-b. According to some embodiments, a thickness of each of the plurality of thin films may be in a range of about 50 nm to about 5 um, about 50 nm to about 10 nm, about 50 nm to about 20 nm, about 40 nm to about 20 nm, about 30 nm to about 5 nm, about 10 nm to about 5 nm, and the like. Each possibility is a separate embodiment.

According to some embodiments, electron filter 216 may be made of or include: (a) Mylar and Hf, (b) Mylar and Fe, (c) Mylar and Al₂O₃, and (d) Al and Mg. Each possibility is a separate embodiment.

According to some embodiments, band-stop filter 212 may include one or more band-stop filters 214 configured to attenuate X-ray photons having a pre-determined energy. Put differently, in some embodiments, each of filters 214 is configured to attenuate/filter-out X-ray photons having a different respective predetermined energy of X-ray photons, while allowing the transmission of X-ray photons of interest (i.e., X-ray photons having an energy of interest).

In some embodiments, the pre-determined energy of the attenuated X-ray photons may be in a range of about 50 eV to about 15 KeV. In some embodiments, the pre-determined energy of the attenuated X-ray photons may be in a range of about 50 eV to about 30 KeV.

According to some embodiments, the composition of band-stop filter 212, i.e., the materials from which each of filter layers 114 is made may be decide according to the nature of the photons of interest and/or the irrelevant photons. According to some embodiments, one band-stop filter may be replaced by another band-top filter in the characterization tool, based on the need.

As a non-limiting example, and as schematically depicted in FIG. 2C, filters 214 may include a first, a second and a third layers/thin films 214a-c. According to some embodiments, filter 214 may be in the form of a plurality of stacked films/layers having a pre-determined and/or tailored transmission properties. It may be understood by the skilled in the art that the number of the one or more additional band-stop filters may vary.

According to some embodiments, a thickness of each of the layers/thin films of one or more additional band-stop filters 214 may be in a range of about 50 nm to about 5 um, about 50 nm to about 10 nm, about 50 nm to about 20 nm, about 40 nm to about 20 nm, about 30 nm to about 5 nm, about 10 nm to about 5 nm, and the like. Each possibility is a separate embodiment.

As a non-limiting example, band-stop filter 212 may include a window function having an energy line pass of Hf and a line cut of Si, wherein the plurality of thin films includes a back-scattered electron filter, and wherein at least a portion of the plurality of thin films is made of or includes Mylar and Hf.

As another non-limiting example, band-stop filter 212 may include a window function having an energy line pass of F, Fe and a line cut of Co, wherein the plurality of thin films includes a back-scattered electron filter, and wherein at least a portion of the plurality of thin films of the band-stop filter is made of or includes Mylar and Fe.

As another non-limiting example, band-stop filter 212 may include a window function having an energy line pass of Al and a line cut of Si, wherein the plurality of thin films includes a back-scattered electron filter, and wherein at least a portion of the plurality of thin films of the band-stop filter is made of or includes Mylar and Al₂O₃.

As another non-limiting example, band-stop filter 212 may include a window function having an energy line pass of Ge and a line cut of Si, wherein the plurality of thin films includes a back-scattered electron filter, and wherein at least a portion of the plurality of thin films of the band-stop filter is made of or includes Al and Mg.

According to some embodiments, band-stop filter 212 may be devoid of the back-scattered electron filter.

As a non-limiting example, band-stop filter 212 may include a window function having an energy line pass of Hf and a line cut of Si, wherein the band-stop filter is devoid of the backscattered electron filter, and wherein at least a portion of the plurality of thin films of the band-stop filter is made of or includes Hf.

As another non-limiting example, band-stop filter 212 may include a window function having an energy line pass of Ge and a line cut of Si, wherein the band-stop filter is devoid of the backscattered electron filter, and wherein at least a portion of the plurality of thin films of the band-stop filter is made of or includes Al.

As another non-limiting example, band-stop filter 212 may include a window function having an energy line pass of N and a line cut of Ti, wherein the band-stop filter is devoid of the backscattered electron filter, and wherein at least a portion of the plurality of thin films of the band-stop filter is made of or includes BN.

As another non-limiting example, band-stop filter 212 may include a window function having an energy line pass of N and a line cut of Ti, wherein the band-stop filter is devoid of the backscattered electron filter, and wherein at least a portion of the plurality of thin films of the band-stop filter is made of or includes TiN.

As another non-limiting example, band-stop filter 212 may include a window function having an energy line pass of N and a line cut of Ti, wherein the band-stop filter is devoid of the backscattered electron filter, and wherein at least a portion of the plurality of thin films of the band-stop filter is made of or includes Si₃N₄.

As another non-limiting example, band-stop filter 212 may include a window function having an energy line pass of N, Ti and a line cut of O, wherein the band-stop filter is devoid of the backscattered electron filter, and wherein at least a portion of the plurality of thin films of the band-stop filter is made of or includes V.

As another non-limiting example, band-stop filter 212 may include a window function having an energy line pass of N, Ti and a line cut of O, wherein the band-stop filter is devoid of the backscattered electron filter, and wherein at least a portion of the plurality of thin films of the band-stop filter is made of or includes Ti.

As another non-limiting example, band-stop filter 212 may include a window function having an energy line pass of F and a line cut of Fe, wherein the band-stop filter is devoid of the backscattered electron filter, and wherein at least a portion of the plurality of thin films of the band-stop filter is made of or includes Teflon.

As another non-limiting example, band-stop filter 212 may include a window function having an energy line pass of O and a line cut of Fe, F, wherein the band-stop filter is devoid of the backscattered electron filter, and wherein at least a portion of the plurality of thin films of the band-stop filter is made of or includes Mn.

As another non-limiting example, band-stop filter 212 may include a window function having an energy line pass of O and a line cut of F, wherein the band-stop filter is devoid of the backscattered electron filter, and wherein at least a portion of the plurality of thin films of the band-stop filter is made of or includes Cr.

As another non-limiting example, band-stop filter 212 may include a window function having an energy line pass of F, Fe and a line cut of Co, wherein the band-stop filter is devoid of the backscattered electron filter, and wherein at least a portion of the plurality of thin films of the band-stop filter is made of or includes Fe.

As another non-limiting example, band-stop filter 212 may include a window function having an energy line pass of Al and a line cut of Si, wherein the band-stop filter is devoid of the backscattered electron filter, and wherein at least a portion of the plurality of thin films of the band-stop filter is made of or includes Al₂O₃.

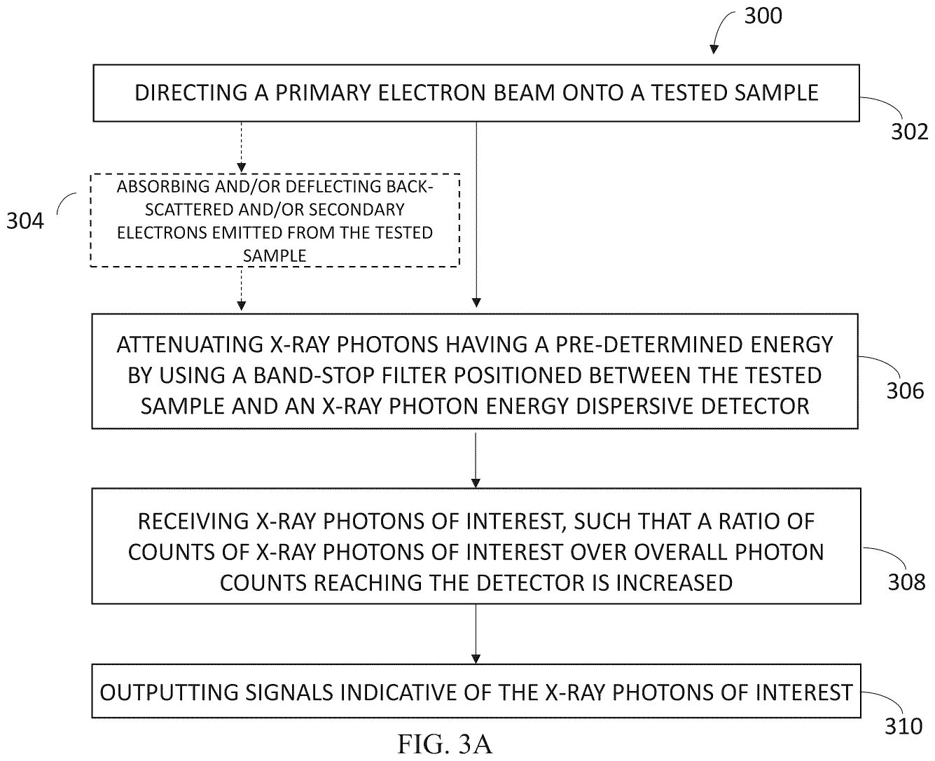

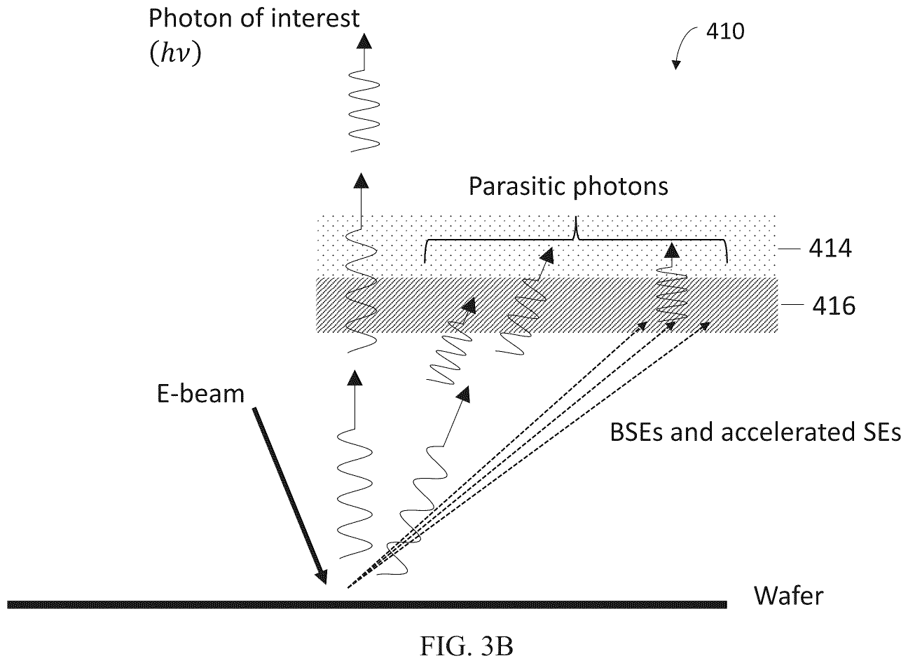

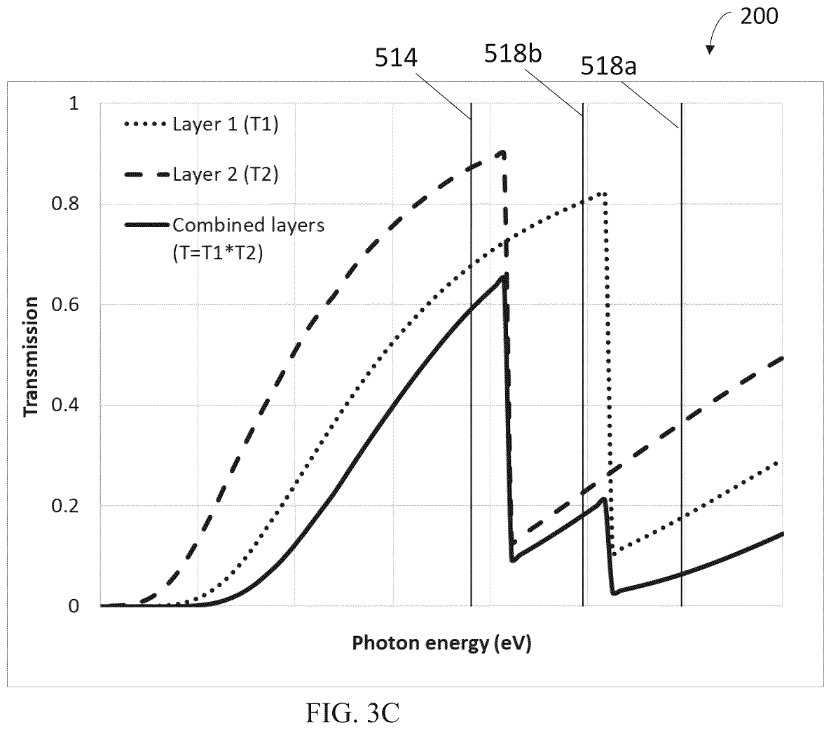

According to an aspect of some embodiments, there is provided a method for filtering photons by energy. According to some embodiments, the disclosed method may be utilized for metrology of specimens based, e.g., on electron microscopy. FIG. 3A presents a flowchart of such a method, namely method 300, according to some embodiments. Method 300 may be implemented using system 100 and a system similar thereto. Reference is also made to FIGS. 3B-C, which are exemplary illustrations of a filtering system 410 in operation, according to some embodiments. It is noted that an electron beam and a tested sample 422 do not form part of filtering system 410.

According to some embodiments, at step 302, the method may include directing a primary electron beam (marked as “E-beam” in FIG. 3B) onto a tested sample, thereby initiating emission of X-ray photons and of electrons from the tested sample. As a non-limiting example, the primary electron beam may be generated by an electron gun of a SEM, TEM, and the like.

Each possibility is a separate embodiment.

According to some embodiments, and as schematically depicted in FIG. 3B, as a result of the striking of the E-beam on a tested sample 422, X-ray photons, back-scattered electrons and secondary electrons (SE) may be emitted from tested sample 422. In some embodiments, a first portion of the X-ray photons may include photons of interest, and a second portion of the X-ray photons may include parasitic/irrelevant photons. Optionally, in some embodiments, the emitted back-scatted electrons and/or secondary electrons may also be referred to as parasitic/irrelevant signals emitted from tested sample 422.

According to some embodiments, at step 304, which is an optional step, the method may include attenuating back-scattered and/or secondary electrons emitted from the tested sample using an electron filter (such as electron filter 416). According to some embodiments, the electron filter may also absorb/attenuate at least a portion of the photons. According to some embodiments, the electron filter may be configured to attenuate photons of a certain energy so as to minimize attenuation/absorption of photons of interest. According to some embodiments, if no electron filter is applied, the electrons may otherwise be deflected from the band-stop filter.

According to some embodiments, at step 306, the method may include attenuating X-ray photons having a pre-determined energy by using a band-stop filter (such as band-stop filter 414) positioned between the tested sample and an X-ray photon energy dispersive detector.

According to some embodiments, step 306 may optionally include a plurality of predetermined energies of X-ray photons by the band stop filter and one or more additional band-stop filters (not shown in FIG. 3B).

It is understood that if an electron filter is included, the electron filter, it is positioned such that the electrons emitted from the sample reach the electron filter prior to reaching the band-stop filter.

According to some embodiments, at step 308, the method may include receiving, by the X-ray photon energy dispersive detector, X-ray photons of interest, such that a ratio of counts of X-ray photons of interest reaching the detector over overall photon counts reaching the detector is increased.

According to some embodiments, the ratio of counts may be increased by about a factor of about 5 or more, about 6 or more, about 7 or more, about 8 or more, about 9 or more, about 10 or more. Each possibility is a separate embodiment.

According to some embodiments, at step 310, the method may include outputting signals indicative of the X-ray photons of interest.

Reference in now made to FIG. 3C which shows the transmission of photons emitted from a sample in response to an electron beam having impinged thereon. The dotted line shows the transmission of photons obtained when passing through a first filter layer (T1), the dashed line the transmission of photons obtained when passing through a second filter layer (T2), and the full line the transmission of photons obtained when passing through both the first and the second filter layer (T1*T2). Vertical line 514 represents a photon energy of a photon of interest, i.e. the photons which should reach the EDX detector. Vertical lines 518a and 518b represent a photon energy of parasitic photons (i.e. photons that do not carry information of interest). Vertical line 518a represent parasitic photons emitted by the sample as a result of the electron beam impinging thereon. Vertical line 518b represent parasitic photons emitted as a result of backscattered electrons and/or secondary electrons impinging on the first filter.

As seen from the figure, applying any of the first or second filter layers significantly attenuates the count of parasitic photons (without a filter all photons would be transmitted—i.e., a flat line at transmission=1 would be obtained). Moreover, while a combination of filter layer 1 and filter layer 2 result in an overall reduction in the counts of photons of interest transmitted to the EDX, this reduction is significantly lower than the reduction obtained for the parasitic photons, i.e. only about 10% of the silicon photons reach the EDX and the count of photons resulting from back-scattered electrons reaching the EDX is also significantly reduced. This advantageously means that the ratio of counts of X-ray photons of interest reaching the detector over overall photon counts reaching the detector is further increased as compared to using a single filter.

According to some embodiments, the term “specimen” may refer to a semiconductor device and/or a component/element thereof. According to some embodiments, the term “specimen” may refer to a wafer (e.g., a Si wafer, a GaAs wafer, and the like), such as a patterned wafer, a non-patterned wafer, and the like. According to some embodiments, the term “specimen” may refer to a diode, a transistor, an integrated circuit, a system on a chip, and the like, and/or any component/element thereof. According to some embodiments, the term “specimen” may refer to an electronic device and/or components/elements thereof. According to some embodiments, the term “specimen” may refer to an energy store device or a component/element thereof. According to some embodiments, the term “specimen” may refer to an optoelectronic device or any component/element thereof. According to some embodiments, the term “specimen”may refer to a photoresist. Each possibility is a separate embodiment.

In the description and claims of the application, the words “include” and “have”, and forms thereof, are not limited to members in a list with which the words may be associated.

As used herein, the term “about” may be used to specify a value of a quantity or parameter (e.g., the length of an element) to within a continuous range of values in the neighborhood of (and including) a given (stated) value. According to some embodiments, “about” may specify the value of a parameter to be between 80 % and 120 % of the given value. For example, the statement “the length of the element is equal to about 1 m” is equivalent to the statement “the length of the element is between 0.8 m and 1.2 m”. According to some embodiments, “about” may specify the value of a parameter to be between 90 % and 110 % of the given value. According to some embodiments, “about” may specify the value of a parameter to be between 95 % and 105 % of the given value.

As used herein, according to some embodiments, the terms “substantially” and “about” may be interchangeable.

As used herein, according to some embodiments, the terms “sample” and “specimen” may be interchangeable.

According to some embodiments, the term “specimen” may refer to any type of a sample suitable for characterization under illumination of an electron beam. As a non-limiting example, the term “specimen” may refer to any type of a sample suitable for characterization by utilizing a scanning electron microscope.

The skilled person will readily perceive that the order in which the above operations are listed is not unique.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. No feature described in the context of an embodiment is to be considered an essential feature of that embodiment, unless explicitly specified as such.

Although stages of methods according to some embodiments may be described in a specific sequence, methods of the disclosure may include some or all of the described stages carried out in a different order. A method of the disclosure may include a few of the stages described or all of the stages described. No particular stage in a disclosed method is to be considered an essential stage of that method, unless explicitly specified as such.

Although the disclosure is described in conjunction with specific embodiments thereof, it is evident that numerous alternatives, modifications, and variations that are apparent to those skilled in the art may exist. Accordingly, the disclosure embraces all such alternatives, modifications, and variations that fall within the scope of the appended claims. It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purpose and should not be regarded as limiting. Citation or identification of any reference in this application shall not be construed as an admission that such reference is available as prior art to the disclosure. Section headings are used herein to ease understanding of the specification and should not be construed as necessarily limiting.

What is claimed is:

1. A sample characterization system comprising:
a characterization tool configured to generate an electron beam directed toward a tested sample;
an X-ray photon energy dispersive detector (EDX) configured to collect X-ray photons emitted from the tested sample; and
a filter assembly positioned in the characterization tool between the tested sample and the EDX, the filter assembly comprising a band-stop filter configured to allow transmission therethrough of information-carrying X-ray photons having a predetermined energy range and attenuating irrelevant photons having an energy range different from the predetermined energy range from reaching the EDX, whereby a ratio between a count of information-carrying X-ray photons reaching the EDX and an overall photon count reaching the EDX is increased, as compared to a sample characterization system without the filter assembly.

2. The system of claim 1, wherein the filter assembly further comprises an electron filter configured to attenuate back-scattered electrons emitted from the tested sample; and/or wherein the filter assembly further comprises a deflector configured to deflect electrons away from the filter assembly.

3. The system of claim 1, wherein the filter assembly further comprises one or more additional band-stop filters, wherein each of the one or more additional band-stop filters is configured to filter out X-ray photons having a different respective predetermined energy of X-ray photons.

4. The system of claim 1, wherein at least a portion of the band-stop filter is made of or comprises a plurality of thin films.

5. The system of claim 4, wherein a thickness of each of the plurality of thin films is in a range of 50 nm to 5 um.

6. The system of claim 4, wherein at least a portion of the plurality of thin films comprises: Hf, Al, BN, TiN, Si₃N₄, V, Ti, Teflon, Mn, Cr, Fe, Al₂O₃ or any combination thereof.

7. The system of claim 4, wherein at least a portion of the plurality of thin films comprises:
a. Mylar and Hf,
b. Mylar and Fe,
c. Mylar and Al₂O₃, or
d. Al and Mg.

8. The system of claim 1, wherein the band-stop filter is a notch filter.

9. The system of claim 1, wherein the filter assembly or parts thereof are replaceable in-situ.

10. The system of claim 1, wherein the ratio is increased by a factor of 8 or more.

11. The system of claim 1, wherein the predetermined energy range is about 50 eV to 15 KeV.

12. The system of claim 1, wherein the predetermined energy range is adjustable, thereby allowing tailoring a value thereof.

13. The system of claim 1, wherein the characterization tool comprises an electron microprobe, a scanning electron microscope (SEM), a transmission electron microscope (TEM), or a scanning TEM (STEM).

14. A method for filtering photons by energy, comprising:
directing a primary electron beam onto a tested sample, thereby initiating emission of X-ray photons and of electrons from the tested sample;
attenuating X-ray photons having an energy different than a predetermined energy range of information-carrying X-ray photons by using a band-stop filter positioned between the tested sample and the EDX;
detecting, by the EDX, the information-carrying X-ray photons, thereby a ratio between a count of information-carrying X-ray photons reaching the EDX and an overall photon count reaching the EDX is increased as compared to a sample characterization system without the filter assembly; and
outputting signals indicative of the information-carrying X-ray photons detected by the EDX.

15. The method of claim 14, further comprising attenuating back-scattered and/or secondary electrons emitted from the tested sample; and/or further comprising deflecting backscattered and/or secondary electrons away from the filter assembly.

16. A filter assembly for filtering photons by energy, the filter assembly comprising a band-stop filter configured to allow transmission therethrough of information carrying X-ray photons having a predetermined energy range and inhibiting irrelevant photons from reaching an energy dispersive detector (EDX), whereby a ratio between a count of information-carrying X-ray photons reaching the EDX and an overall photon count reaching the EDX is increased as compared to a sample characterization system without the filter assembly;
wherein at least a portion of the band-stop filter is made of or comprises a plurality of thin films having a thickness of about 50 nm to 5 um; and
wherein at least a portion of the plurality of thin films comprises a material selected from: Hf, Al, BN, TiN, Si₃N₄, V, Ti, Teflon, Mn, Cr, Fe or Al₂O₃.

17. The filter assembly of claim 16, wherein the ratio of counts is increased by a factor of 8 or more.

18. The filter assembly of claim 16, further comprising an electron filter configured to attenuate back-scattered electrons and/or secondary electrons emitted from the tested sample; and/or further comprising a deflector configured to deflect electrons away from the filter assembly.

19. The filter assembly of claim 16, wherein at least a portion of the plurality of thin films comprises:
a. Mylar and Hf,
b. Mylar and Fe,
c. Mylar and Al₂O₃, or
d. Al and Mg.

20. The filter system of claim 16, wherein the predetermined energy is in a range of 50 eV to 15 KeV.
